(19) United States
(12) Patent Application Publication
(10) Pub. No.: US 2026/0083010 A1
(43) Pub. Date: Mar. 19, 2026

(54) SEMICONDUCTOR PACKAGE

(71) Applicant: SAMSUNG ELECTRONICS CO., LTD., Suwon-si (KR)

(72) Inventors: Wonho CHOI, Suwon-si (KR); Juil CHOI, Suwon-si (KR); Gyuho KANG, Suwon-si (KR); Seonghoon BAE, Suwon-si (KR); Kwangok JEONG, Suwon-si (KR)

(73) Assignee: SAMSUNG ELECTRONICS CO., LTD., Suwon-si (KR)

(21) Appl. No.: 19/206,646

(22) Filed: May 13, 2025

(30) Foreign Application Priority Data
Sep. 19, 2024 (KR) 10-2024-0126377

(51) Int. Cl. H01L 25/18; H01L 23/00; H01L 23/31; H01L 23/498; H01L 23/538; H01L 25/065; H10B 80/00; H10D 80/30

(52) U.S. Cl. CPC H10W 90/00; H10B 80/00; H10D 80/30; H10W 70/611; H10W 74/121; H10W 74/127; H10W 90/401; H10W 90/701; H10W 72/823; H10W 72/879; H10W 74/15; H10W 90/297; H10W 90/722; H10W 90/724; H10W 90/732; H10W 90/734; H10W 90/754

(57) ABSTRACT

A semiconductor package may include a buffer die including a plurality of first wire bonding pads, a first group of core dies sequentially stacked on the buffer die, a first interposer on the first group of core dies and including a plurality of first lower connection pads in a lower surface of the first interposer to face the plurality of first wire bonding pads, respectively, a plurality of first conductive wires extending vertically from the plurality of first wire bonding pads between the buffer die and the first interposer, the plurality of first conductive wires being connected to the plurality of first lower connection pads, respectively, and a second group of core dies sequentially stacked on the first interposer.

### CROSS-REFERENCE TO RELATED APPLICATION

This application claims priority under 35 U.S.C. § 119 to Korean Patent Application No. 10-2024-0126377, filed on Sep. 19, 2024, in the Korean Intellectual Property Office (KIPO), the disclosure of which is herein incorporated by reference in its entirety.

### BACKGROUND

### 1. Field

Example embodiments of the present disclosure relate to a semiconductor package and a method of manufacturing the semiconductor package. More particularly, example embodiments of the present disclosure relate to a semiconductor package including a plurality of sequentially stacked semiconductor chips and a method of manufacturing the same.

### 2. Description of Related Art

A large-capacity memory such as High Bandwidth Memory (HBM) may be implemented by vertically stacking a plurality of semiconductor dies using Through Silicon Via (TSV) technology. As the number of the stacked semiconductor dies increases and pitches and diameters of the TSVs become finer, there is a problem that the intensity of a power signal transmitted from a buffer die to a middle core die and an uppermost core die is weakened, thereby deteriorating the function of the core dies.

### SUMMARY

According to example embodiments of the present disclosure, a semiconductor package including stacked dies at an ultra-high-level and having improved power transmission characteristics may be provided.

According to example embodiments of the present disclosure, a semiconductor package may be provided and include: a buffer die including a first region and a second region at a side of the first region, wherein a plurality of first wire bonding pads are in an upper surface of the second region; a first group of core dies sequentially stacked on the first region of the buffer die; a first interposer on an uppermost core die among the first group of core dies, the first interposer including a third region overlapping the first region and a fourth region overlapping the second region, wherein a plurality of first lower connection pads are in a lower surface of the fourth region to face the plurality of first wire bonding pads, respectively; a plurality of first conductive wires extending vertically from the plurality of first wire bonding pads between the second region of the buffer die and the fourth region of the first interposer, the plurality of first conductive wires connected to the plurality of first lower connection pads, respectively; and a second group of core dies sequentially stacked on the first interposer.

According to example embodiments of the present disclosure, a semiconductor package may be provided and include a base stack structure including: a buffer die including a first region and a second region at a side of the first region; a first group of core dies sequentially stacked on the first region of the buffer die; a plurality of first conductive wires extending in a vertical direction from a plurality of first wire bonding pads on the second region of the buffer die; and a first sealing member on the buffer die, the first group of core dies, and the plurality of first conductive wires, the first sealing member exposing end portions of the plurality of first conductive wires. The semiconductor package may further include a first die stack structure on the base stack structure, the first die stack structure including: a first interposer including a third region overlapping the first region and a fourth region overlapping the second region; and a second group of core dies sequentially stacked on the first interposer, wherein the plurality of first conductive wires are connected to the second group of core dies by the first interposer.

According to example embodiments of the present disclosure, a semiconductor package may be provided and include: a buffer die including a first region and a second region at a side of the first region, wherein a plurality of first wire bonding pads are in the second region; a plurality of core dies sequentially stacked on the first region of the buffer die; an interposer between a pair of core dies from among the plurality of core dies, the interposer including a third region overlapping the first region and a fourth region overlapping the second region, wherein a plurality of lower connection pads are in the fourth region to face the plurality of first wire bonding pads, respectively; a plurality of conductive wires extending vertically between the buffer die and the interposer from the plurality of first wire bonding pads, the plurality of conductive wires being connected to the plurality of lower connection pads, respectively; a sealing member between the buffer die and the interposer, the sealing member being on the plurality of conductive wires and on at least two from among the plurality of core dies, and exposing end portions of the plurality of conductive wires; a plurality of second wire bonding pads respectively on the end portions of the plurality of conductive wires, the end portions exposed from an upper surface of the sealing member; and conductive bumps between the plurality of second wire bonding pads and the plurality of lower connection pads.

According to example embodiments of the present disclosure, a semiconductor package may include a first group of core dies sequentially stacked on a buffer die, a first interposer stacked on the first group of the core dies, a second group of core dies sequentially stacked on the first interposer, a second interposer stacked on a second group of the core dies, and a third group of core dies sequentially stacked on the second interposer.

A power signal supplied to the buffer die may be transmitted to the second group of core dies through the first interposer via first conductive wires on the buffer die. An electrical signal supplied to the first interposer may be transmitted to the third group of core dies through the second interposer via second conductive wires on the first interposer.

Accordingly, the intensity of the power signal transmitted from the buffer die to a middle core die and an uppermost core die may be prevented from being weakened.

### BRIEF DESCRIPTION OF DRAWINGS

Example embodiments will be more clearly understood from the following detailed description taken in conjunction with the accompanying drawings. FIGS. 1 to 32 represent non-limiting example embodiments as described herein.

FIG. 1 is a cross-sectional view illustrating a semiconductor package in accordance with example embodiments.

FIG. 2 is a plan view illustrating a base stack structure of the semiconductor package of FIG. 1.

FIG. 3 is a plan view illustrating a first die stack structure of the semiconductor package of FIG. 1.

FIG. 4 is a plan view illustrating a second die stack structure of the semiconductor package of FIG. 1.

FIG. 5 is an enlarged cross-sectional view illustrating a portion B1 in FIG. 1.

FIG. 6 is an enlarged cross-sectional view illustrating a portion B2 in FIG. 1.

FIG. 7 is an enlarged cross-sectional view illustrating a portion B3 in FIG. 1.

FIGS. 8 to 30 are views illustrating a method of manufacturing a semiconductor package in accordance with example embodiments.

FIG. 31 is a cross-sectional view illustrating a semiconductor package in accordance with example embodiments.

FIG. 32 is an enlarged cross-sectional view illustrating a portion G1 in FIG. 31.

### DETAILED DESCRIPTION

Hereinafter, non-limiting example embodiments of the present disclosure will be explained in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

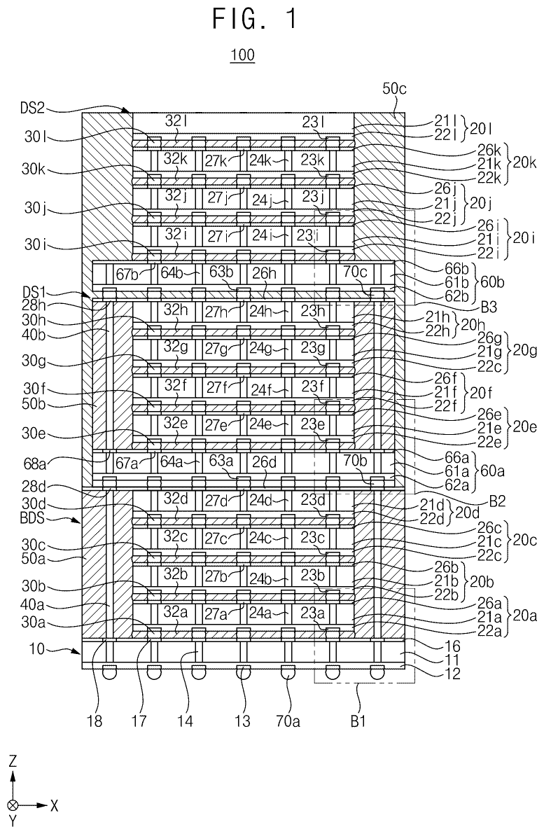

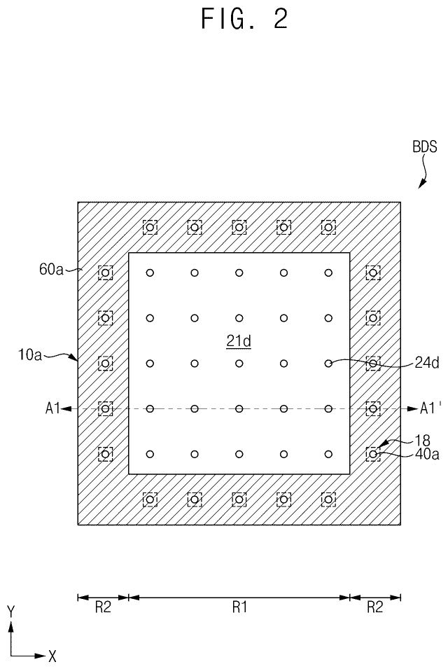

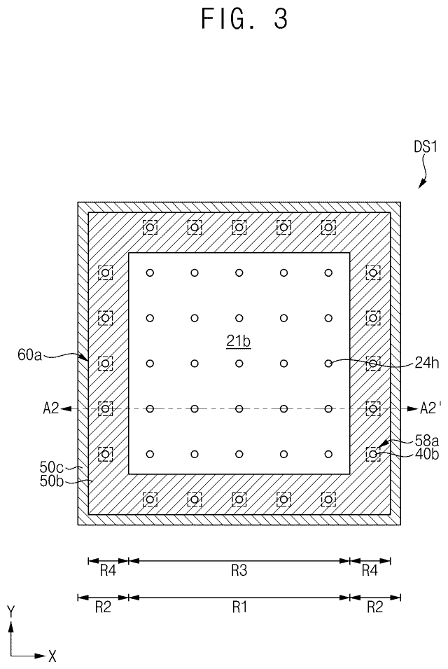

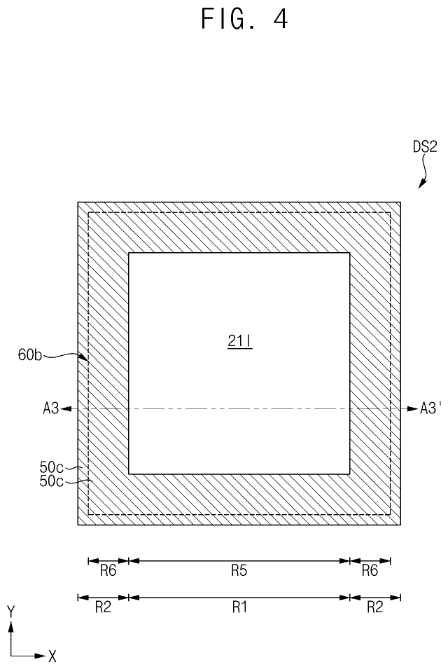

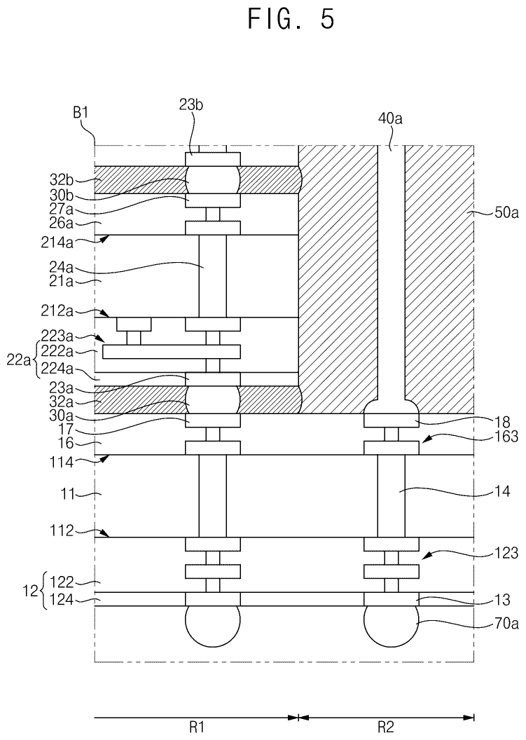

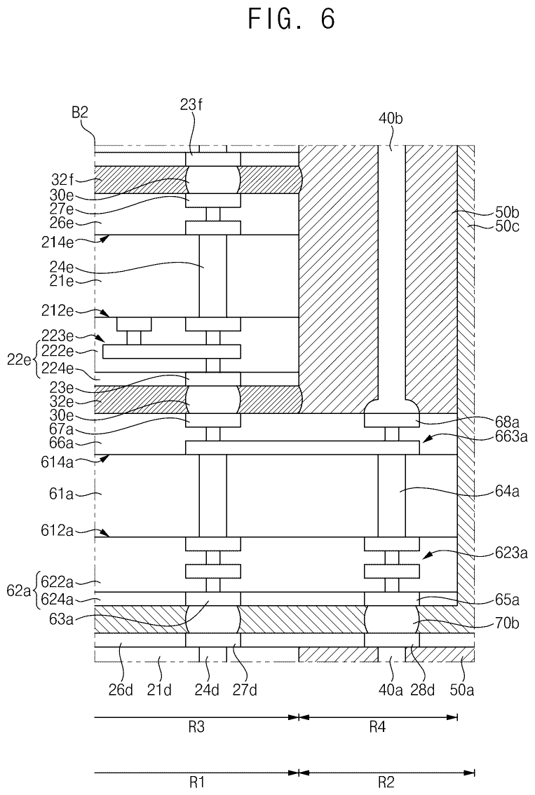

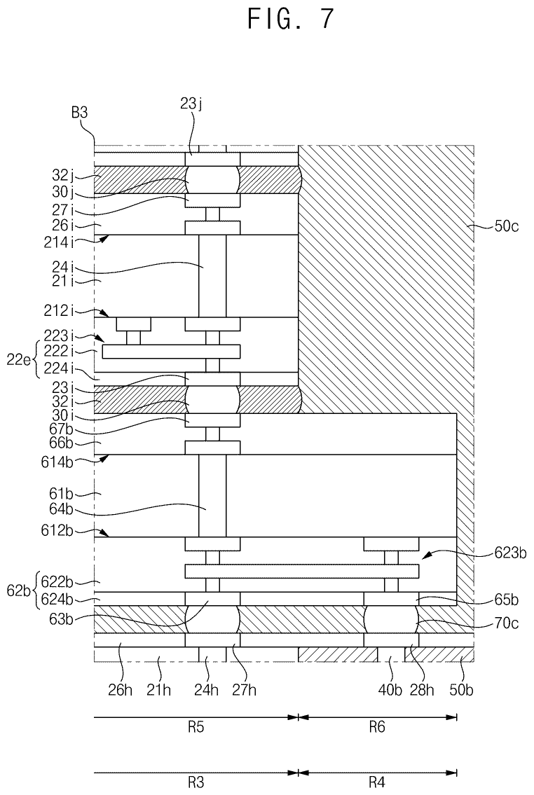

FIG. 1 is a cross-sectional view illustrating a semiconductor package in accordance with example embodiments. FIG. 2 is a plan view illustrating a base stack structure of the semiconductor package of FIG. 1. FIG. 3 is a plan view illustrating a first die stack structure of the semiconductor package of FIG. 1. FIG. 4 is a plan view illustrating a second die stack structure of the semiconductor package of FIG. 1. FIG. 5 is an enlarged cross-sectional view illustrating a portion B1 in FIG. 1. FIG. 6 is an enlarged cross-sectional view illustrating a portion B2 in FIG. 1. FIG. 7 is an enlarged cross-sectional view illustrating a portion B3 in FIG. 1. FIG. 1 includes a cross-sectional portion cut along the line A1-A1′ in FIG. 2, a cross-sectional portion cut along the line A2-A2′ in FIG. 3, and a cross-sectional portion cut along the line A3-A3′ in FIG. 4.

Referring to FIGS. 1 to 7, a semiconductor package 100 may include semiconductor chips (die) stacked therein. The semiconductor package 100 may include a base die stack structure BDS, at least one first die stack structure DS1 stacked on the base die stack structure BDS, and a second die stack structure DS2 stacked on the at least one first die stack structure DS1.

In example embodiments, the semiconductor package 100 may include a buffer die 10, a first group of core dies (e.g., a first core die 20a, a second core die 20b, a third core die 20c, and a fourth core die 20d) sequentially stacked on the buffer die 10, a first interposer 60a stacked on an uppermost core die (e.g., the fourth core die 20d) among the first group of core dies, a plurality of first conductive wires 40a extending in a vertical direction (Z direction) between the buffer die 10 and the first interposer 60a around the first group of core dies (e.g., the first core die 20a, the second core die 20b, the third core die 20c, and the fourth core die 20d), and a second group of core dies (e.g., a fifth core die 20e, a sixth core die 20f, a seventh core die 20g, and the eighth core die 20h) sequentially stacked on the first interposer 60a. In addition, the semiconductor package 100 may further include a second interposer 60b stacked on an uppermost core die (e.g., the eighth core die 20h) among the second group of core dies, a plurality of second conductive wires 40b extending in the vertical direction (Z direction) between the first interposer 60a and the second interposer 60b around the second group of core dies (e.g., the fifth core die 20e, the sixth core die 20f, the seventh core die 20g, and the eighth core die 20h), and a third group of core dies (e.g., a ninth core die 20i, a tenth core die 20j, a eleventh core die 20k, and a twelfth core die 20l) sequentially stacked on the second interposer 60b.

A plurality of semiconductor chips (e.g., the first core die 20a, the second core die 20b, the third core die 20c, the fourth core die 20d, the fifth core die 20e, the sixth core die 20f, the seventh core die 20g, the eighth core die 20h, the ninth core die 20i, the tenth core die 20j, the eleventh core die 20k, and the twelfth core die 20l) (collectively referred to as semiconductor chips) may be vertically stacked. In this embodiment, the semiconductor chips 20 may be substantially the same as or similar to each other. Accordingly, same or like reference numerals will be used to refer to the same or like elements and repeated descriptions of the same elements may be omitted.

In this embodiment, the semiconductor package as a multi-chip package is illustrated as including 12 semiconductor chips that are stacked on the buffer die 10. However, embodiments of the present disclosure are not limited thereto, and for example, the semiconductor package may include 20 or 24 stacked semiconductor chips on the buffer die 10.

Each of the semiconductor chips may include an integrated circuit chip completed by performing semiconductor manufacturing processes. Each semiconductor chip may include, for example, a memory chip or a logic chip. The semiconductor package 100 may include a memory device. The memory device may include a high bandwidth memory (HBM) device.

As illustrated in FIG. 1, the base stack structure BDS may include the buffer die 10, the first group of core dies (e.g., the first core die 20a, the second core die 20b, the third core die 20c, and the fourth core die 20d) sequentially stacked on the buffer die 10, the plurality of first conductive wires 40a extending in the vertical direction from a plurality of first wire bonding pads 18 on a second region R2 of the buffer die 10, and a first sealing member 50a on the buffer die 10 covering the first group of core dies (e.g., the first core die 20a, the second core die 20b, the third core die 20c, and the fourth core die 20d) and the plurality of first conductive wires 40a, and exposing end portions of the first conductive wires 40a. In this embodiment, it will be understood that the base stack structure BDS may include, but is not limited to, core dies (e.g., the first core die 20a, the second core die 20b, the third core die 20c, and the fourth core die 20d) stacked in four stages. For example, the first group of core dies may include 8 or 12 stacked core dies on the buffer die.

In example embodiments, the first group of core dies (e.g., the first core die 20a, the second core die 20b, the third core die 20c, and the fourth core die 20d) may be sequentially stacked on the buffer die 10 via first conductive bumps 30a, 30b, 30c, and 30d. The first group of core dies (e.g., the first core die 20a, the second core die 20b, the third core die 20c, and the fourth core die 20d) may be sequentially attached on the buffer die 10 by first adhesive layers 32a, 32b, and 32c, 32d.

In example embodiments, the buffer die 10 may include a substrate 11, a front insulating layer 12, a plurality of first bonding pads 13, a plurality of through electrodes 14, a backside insulating layer 16, and a plurality of second bonding pads 17. In addition, the buffer die 10 may further include conductive bumps 70a as external connection members respectively provided on the first bonding pads 13. The buffer die 10 may be mounted on a package substrate or an interposer via the conductive bumps 70a. For example, the conductive bump 70a may include a solder bump. Alternatively, the conductive bump 70a may include a pillar bump and a solder bump formed on the pillar bump.

The substrate 11 may have a first surface 112 and a second surface 114 opposite to the first surface 112. The first surface 112 may be an active surface, and the second surface 114 may be an inactive surface. Circuit patterns may be provided in the first surface 112 of the substrate 11. The first surface 112 may be referred to as a front side surface in which the circuit patterns are formed, and the second surface 114 may be referred to as a backside surface.

For example, the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIGS. 2 and 5, a first core die 20a of the base stack structure BDS may include a substrate 21a, a front insulating layer 22a, a plurality of first bonding pads 23a, a plurality of through electrodes 24a, a backside insulating layer 26a, and a plurality of second bonding pads 27a. A first conductive bump 30a formed on the first bonding pad 23a of the first core die 20a may be bonded to the second bonding pad 17 of the buffer die 10. The first bonding pad 23a of the first core die 20a may be electrically connected to the second bonding pad 17 of the buffer die 10 by the first conductive bump 30a.

The buffer die 10 may include a first region R1 and a second region R2 at a side of the first region R1. The first group of core dies (e.g., the first core die 20a, the second core die 20b, the third core die 20c, and the fourth core die 20d) may be stacked on the first region R1. The second region R2 may be provided to surround the first region R1. The buffer die 10 may include the plurality of first wire bonding pads 18 in the second region R2. The plurality of first wire bonding pads 18 may be arranged within the second region R2 to be spaced apart from each other along one side of the buffer die 10. The second bonding pads 17 and the first wire bonding pads 18 of the buffer die 10 may be provided in the backside insulating layer 16 on the second surface 114 of the substrate 11.

The first conductive wires 40a may extend in the vertical direction (Z direction) from the first wire bonding pads 18, respectively. For example, the first conductive wires 40a may be bonding wires formed by a bonding wire process. The first sealing member 50a may cover outer side surfaces of the first group of core dies (e.g., the first core die 20a, the second core die 20b, the third core die 20c, and the fourth core die 20d) and outer side surfaces of the plurality of first conductive wires 40a on the second region R2 of the buffer die 10. The first sealing member 50a may expose upper portions of the first conductive wires 40a.

A backside insulating layer 26d of the fourth core die 20d, which may be an uppermost core die among the first group of the core dies, may extend laterally from a second surface of a substrate 21d to cover an upper surface of the first sealing member 50a. The upper surface of the first sealing member 50a may be positioned on the same plane as a plane of the second surface of the substrate 21d of the fourth core die 20d. A second bonding pad 27d and a second wire bonding pad 28d may be provided in the backside insulating layer 26d. The second bonding pad 27d may be disposed on an exposed surface of the through electrode 24d. The second wire bonding pad 28d may be disposed on an exposed surface of the first conductive wire 40a. Accordingly, the first wire bonding pads 18 and the second wire bonding pads 28d may be electrically connected to each other by the first conductive wire 40a.

In example embodiments, the first die stack structure DS1 may be stacked on the base die stack structure BDS. The first die stack structure DS1 may include the first interposer 60a, the second group of core dies (e.g., the fifth core die 20e, the sixth core die 20f, the seventh core die 20g, and the eighth core die 20h) sequentially stacked on the first interposer 60a, the plurality of second conductive wires 40b extending in the vertical direction from a plurality of third wire bonding pads 68a on a fourth region R4 of the first interposer 60a, and the second sealing member 50b on the first interposer 60a covering the second group of core dies (e.g., the fifth core die 20e, the sixth core die 20f, the seventh core die 20g, and the eighth core die 20h) and the plurality of second conductive wires 40b and exposing end portions of the second conductive wires 40b. In this embodiment, the first die stack structure DS1 may include the core dies (e.g., the fifth core die 20e, the sixth core die 20f, the seventh core die 20g, and the eighth core die 20h) stacked in four stages, but it will be understood that embodiments of the present disclosure are not limited thereto. For example, the second group of the core dies may include eight or twelve stacked core dies on the first interposer.

The second group of core dies of (e.g., the fifth core die 20e, the sixth core die 20f, the seventh core die 20g, and the eighth core die 20h) may be sequentially stacked on the first interposer 60a via second conductive bumps 30e, 30f, 30g, 30h. The second group of core dies (e.g., the fifth core die 20e, the sixth core die 20f, the seventh core die 20g, and the eighth core die 20h) may be sequentially attached on the first interposer 60a by second adhesive layers 32e, 32f, 32g, 32h.

As illustrated in FIGS. 3 and 6, the first interposer 60a may include an interposer substrate 61a, a front insulating layer 62a, a plurality of first bonding pads 63a, a plurality of through electrodes 64a, a backside insulating layer 66a, and a plurality of second bonding pads 67a. In addition, the first interposer 60a may further include third conductive bumps 70b as external connecting members, which are respectively provided on the first bonding pads 63a.

The first interposer 60a may include a third region R3 and a fourth region R4 at a side of the third region R3. The second group of core dies (e.g., the fifth core die 20e, the sixth core die 20f, the seventh core die 20g, and the eighth core die 20h) may be stacked on the third region R3. The fourth region R4 may be provided to surround the third region R3. The first die stack structure DS1 may be arranged on the base stack structure BDS such that the third region R3 of the first interposer 60a overlaps the first region R1 of the buffer die 10 and the fourth region R4 of the first interposer 60a overlaps the second region R2 of the buffer die 10.

The first interposer 60a may include a plurality of third wire bonding pads 68a at (e.g., in or on) an upper surface of the fourth region R4. The first interposer 60a may include the first bonding pads 63a at (e.g., in or on) a lower surface of the third region R3 and first lower connection pads 65a at (e.g., in or on) a lower surface of the fourth region R4.

The second bonding pads 67a and the third wire bonding pads 68a of the first interposer 60a may be provided in the backside insulating layer 66a on a second surface 614a of the interposer substrate 61a. The second bonding pads 67a of the first interposer 60a may be electrically connected to the first bonding pads 63a by the through electrodes 64a. The third wire bonding pads 68a of the first interposer 60a may be electrically connected to the first lower connection pads 65a by the through electrodes 64a. The second bonding pads 67a and the third wire bonding pads 68a of the first interposer 60a may be electrically connected to each other by wirings 663a in the backside insulating layer 66a. In addition, the second bonding pad 67a and the third wire bonding pad 68a of the first interposer 60a may be electrically connected to each other by wirings in the front insulating layer 62a on a first surface 612a of the interposer substrate 61a.

The second conductive wires 40b may extend in the vertical direction (Z direction) from the second wire bonding pads 28d, respectively. For example, the second conductive wires 40b may be bonding wires formed by a bonding wire process. The second sealing member 50b may be on the fourth region R2 of the first interposer 60a and may cover outer side surfaces of the second group of core dies (e.g., the fifth core die 20e, the sixth core die 20f, the seventh core die 20g, and the eighth core die 20h) and outer side surfaces of the plurality of second conductive wires 40b. The second sealing member 50b may expose upper portions of the second conductive wires 40b.

The second conductive bump 30e formed on the first bonding pad 23e of the fifth core die 20e of the first die stack structure DS1 may be bonded to the second bonding pad 67a of the first interposer 60a. The first bonding pad 23e of the fifth core die 20e may be electrically connected to the second bonding pad 67a of the first interposer 60a by the second conductive bump 30e.

The first interposer 60a may be mounted on the base stack structure BDS via the third conductive bumps 70b. The third conductive bumps 70b on the first interposer 60a may be bonded to the second bonding pad 27d of the fourth core die 20d and the second wire bonding pad 28d of the base stack structure BDS, respectively. Accordingly, the through electrode 24d of the fourth core die 20d may be electrically connected to the second bonding pad 67a of the first interposer 60a by the third conductive bump 70b. The plurality of first conductive wires 40a of the base stack structure BDS may be electrically connected to the plurality of first lower connection pads 65a of the first interposer 60a by the third conductive bumps 70b, respectively.

A backside insulating layer 26h of the eighth core die 20h, which may be an uppermost core die among the second group of the core dies, may extend laterally from a second surface of the substrate 21h to cover an upper surface of the second sealing member 50b. The upper surface of the second sealing member 50b may be positioned on the same plane as a plane of the second surface of the substrate 21h of the eighth core die 20h. A second bonding pad 27h and a fourth wire bonding pad 28h may be provided in the backside insulating layer 26h. The second bonding pad 27h may be disposed on an exposed surface of the through electrode 24h. The fourth wire bonding pad 28h may be disposed on an exposed surface of the second conductive wire 40b. Accordingly, the third wire bonding pad 68a and the second wire bonding pad 28h may be electrically connected to each other by the second conductive wire 40b.

In example embodiments, the second die stack structure DS2 may be stacked on the first die stack structure DS1. The second die stack structure DS2 may include the second interposer 60b and the third group of core dies (e.g., the ninth core die 20i, the tenth core die 20j, the eleventh core die 20k, and the twelfth core die 20l) sequentially stacked on the second interposer 60b. In this embodiment, the second die stack structure DS2 may include core dies (e.g., the ninth core die 20i, the tenth core die 20j, the eleventh core die 20k, and the twelfth core die 20l) stacked in four stages, but it will be appreciated that embodiments of the present disclosure are not limited thereto. For example, the third group of core dies may include 8 or 12 stacked core dies on the second interposer.

The third group of core dies (e.g., the ninth core die 20i, the tenth core die 20j, the eleventh core die 20k, and the twelfth core die 20l) may be sequentially stacked on the second interposer 60b via second conductive bumps 30i, 30j, 30k, 30l. The third group of core dies (e.g., the ninth core die 20i, the tenth core die 20j, the eleventh core die 20k, and the twelfth core die 20l) may be sequentially attached on the second interposer 60b by second adhesive layers 32i, 32j, 32k, 32l.

As illustrated in FIGS. 4 and 7, the second interposer 60b may include an interposer substrate 61b, a front insulating layer 62b, a plurality of first bonding pads 63b, a plurality of through electrodes 64b, a backside insulating layer 66b, and a plurality of second bonding pads 67b. In addition, the second interposer 60b may further include fourth conductive bumps 70c as external connecting members, which are respectively provided on the first bonding pads 63b.

The second interposer 60b may include a fifth region R5 and a sixth region R6 at a side of the fifth region R5. The third group of core dies (e.g., the ninth core die 20i, the tenth core die 20j, the eleventh core die 20k, and the twelfth core die 20l) may be stacked on the fifth region R5. The sixth region R6 may be provided to surround the fifth region R5.

The second die stack structure DS2 may be arranged on the first die stack structure DS1 such that the fifth region R5 of the second interposer 60b overlaps the third region R3 of the first interposer 60a and the sixth region R6 of the second interposer 60b overlaps the fourth region R4 of the first interposer 60a.

The second interposer 60b may include first bonding pads 63b at (e.g., in or on) a lower surface of the fifth region R5 and second lower connection pads 65b at (e.g., in or on) a lower surface of the sixth region R6.

The second bonding pads 67b of the second interposer 60b may be provided in the backside insulating layer 66b on a second surface 614b of the interposer substrate 61b. The second bonding pads 67b of the second interposer 60b may be electrically connected to the first bonding pads 63b by the through electrodes 64b. The second lower connection pad 65b of the second interposer 60b may be electrically connected to the second bonding pad 67b by wirings 623b in the front insulating layer 62b and the through electrode 64b.

The second conductive bump 30i formed on a first bonding pad 23i of the ninth core die 20i of the second die stack structure DS2 may be bonded to the second bonding pad 67b of the second interposer 60b. The first bonding pad 23i of the ninth core die 20i may be electrically connected to the second bonding pad 67b of the second interposer 60b by the second conductive bump 30i

The second interposer 60b may be mounted on the first die stack structure DS1 via the fourth conductive bumps 70c. The fourth conductive bumps 70c on the second interposer 60b may be bonded to the second bonding pad 27h of the eighth core die 20h and the fourth wire bonding pad 28h of the first die stack structure DS1, respectively. Accordingly, the through electrode 24h of the eighth core die 20h may be electrically connected to the second bonding pad 67b of the second interposer 60b by the fourth conductive bump 70c. The plurality of second conductive wires 40b of the first die stack structure DS1 may be electrically connected to the plurality of second lower connection pads 65b of the second interposer 60b by the fourth conductive bumps 70c, respectively.

Since the second lower connection pad 65b is electrically connected to the second bonding pad 67b by the wiring 623b in the front insulating layer 62b and the through electrode 64b, the second conductive wire 40b may be electrically connected to the through electrode 24i of the ninth core die 20i of the second die stack structure DS2.

In example embodiments, the semiconductor package 100 may further include a third sealing member 50c that covers the first die stack structure DS1 and the second die stack structure DS2 sequentially stacked on the base stack structure BDS.

The third sealing member 50c may expose an upper surface of the twelfth core die 20l, which may be an uppermost die of the second die stack structure DS2. The third sealing member 50c may directly contact outer side surfaces of the first die stack structure DS1 and the second die stack structure DS2.

For example, the third sealing member may include a thermosetting resin. The third sealing member may include an epoxy mold compound EMC. The third sealing member may include a UV resin, a polyurethane resin, a silicone resin, a silica filler, etc.

In this embodiment, the semiconductor package 100 is illustrated as including at least one first die stack structure DS1 stacked on the base die stack structure BDS, but it may not be limited thereto, and the semiconductor package 100 may omit the first die stack structure DS1 and may include the base die stack structure BDS and the second die stack structure DS2 stacked directly on the base die stack structure BDS.

As mentioned above, the semiconductor package 100 may include the first group of core dies (e.g., the first core die 20a, the second core die 20b, the third core die 20c, and the fourth core die 20d) sequentially stacked on the buffer die 10, the first interposer 60a stacked on the uppermost core die (e.g., the fourth core die 20d) among the first group of the core dies, and the second group of core dies (e.g., the fifth core die 20e, the sixth core die 20f, the seventh core die 20g, and the eighth core die 20h) sequentially stacked on the first interposer 60a. In addition, the semiconductor package 100 may further include the second interposer 60b stacked on the uppermost core die (e.g., the eighth core die 20h) among the second group of the core dies, and the third group of core dies (e.g., the ninth core die 20i, the tenth core die 20j, the eleventh core die 20k, and the twelfth core die 20l) sequentially stacked on the second interposer 60b.

An electrical signal (e.g., a power signal or a data signal) supplied to the buffer die 10 may be transmitted to the second group of core dies (e.g., the fifth core die 20e, the sixth core die 20f, the seventh core die 20g, and the eighth core die 20h) through the first interposer 60a via the first conductive wires 40a on the second region R2 of the buffer die 10. An electrical signal supplied to the first interposer 60a may be transmitted to the third group of core dies (e.g., the ninth core die 20i, the tenth core die 20j, the eleventh core die 20k, and the twelfth core die 20l) through the second interposer 60b via the second conductive wires 40b on the fourth region R4 of the first interposer 60a.

The first conductive wires 40a, the second conductive wires 40b, the first interposer 60a, and the second interposer 60b may sufficiently transmit the power signal supplied to the buffer die 10 to the middle core dies and the uppermost core die to thereby improve power transmission characteristics. Accordingly, even if the number of stacked core dies increases and pitches and diameters of the through silicon vias become increasingly fine, the intensity of the power signal transmitted from the buffer die to the middle core die and the uppermost core die may be prevented from being weakened.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package in accordance with example embodiments is not limited thereto.

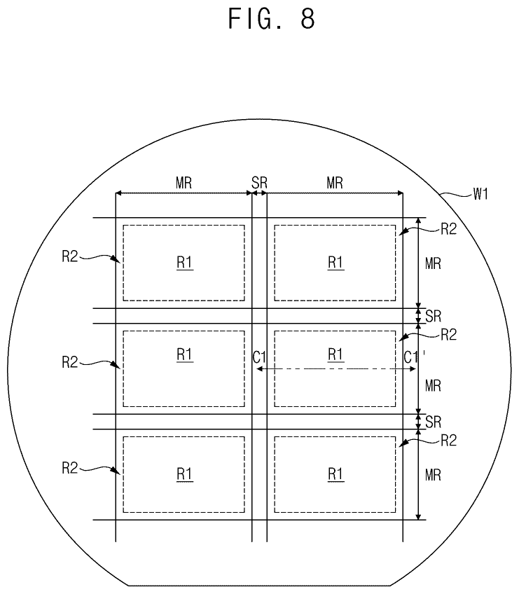

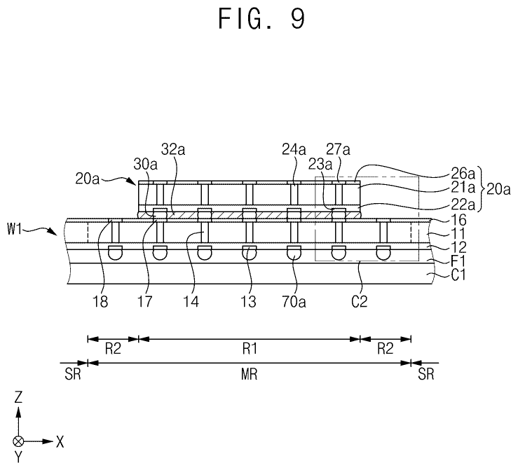

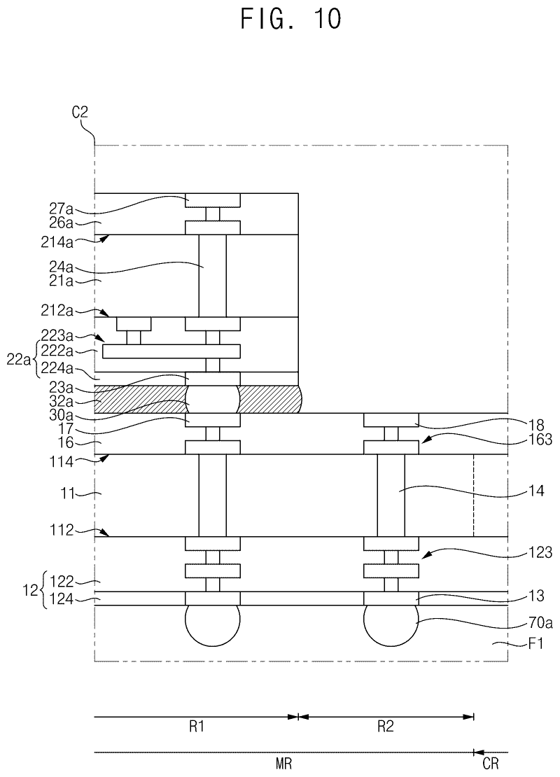

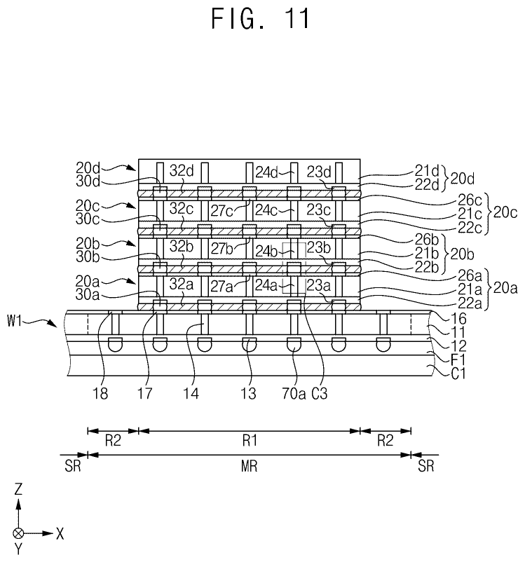

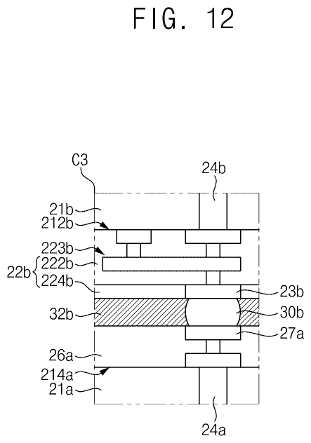

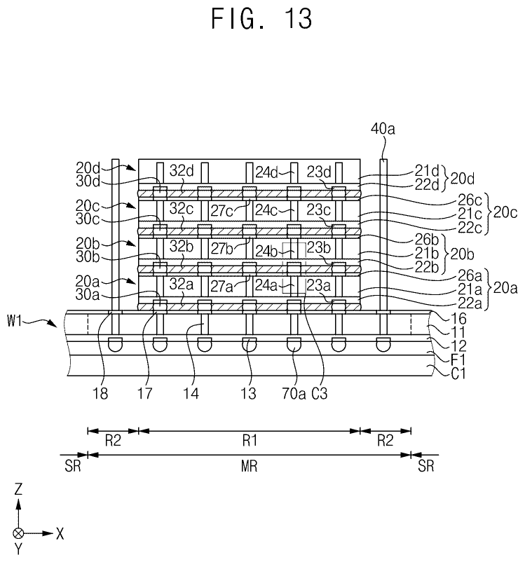

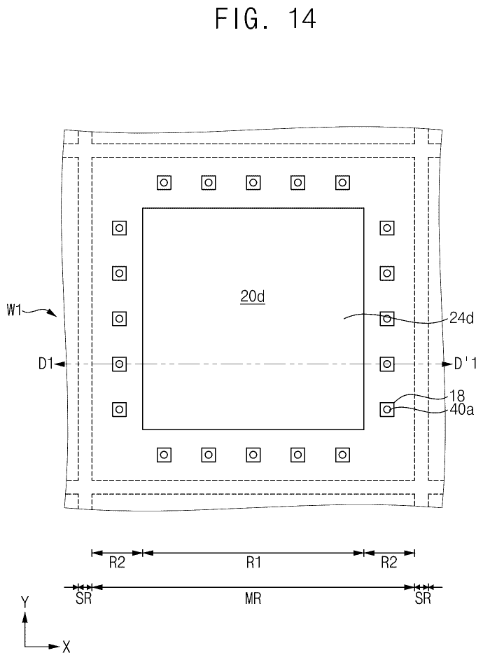

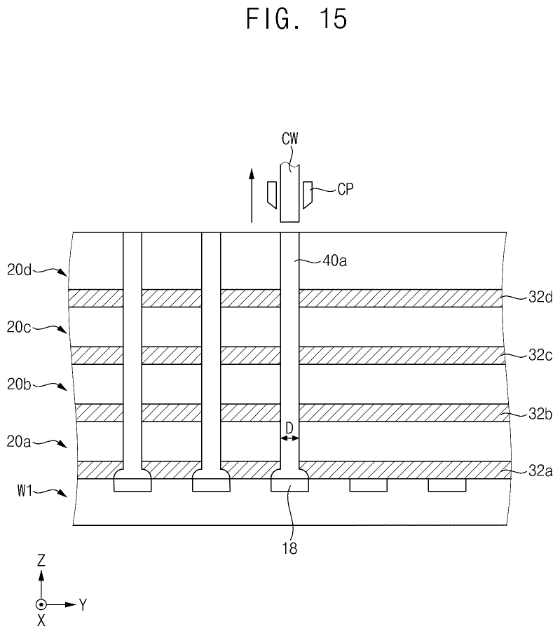

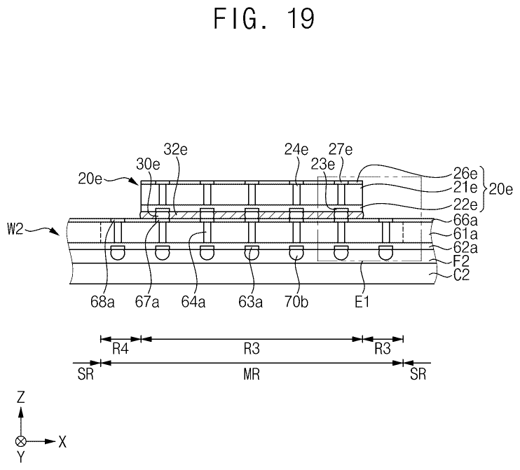

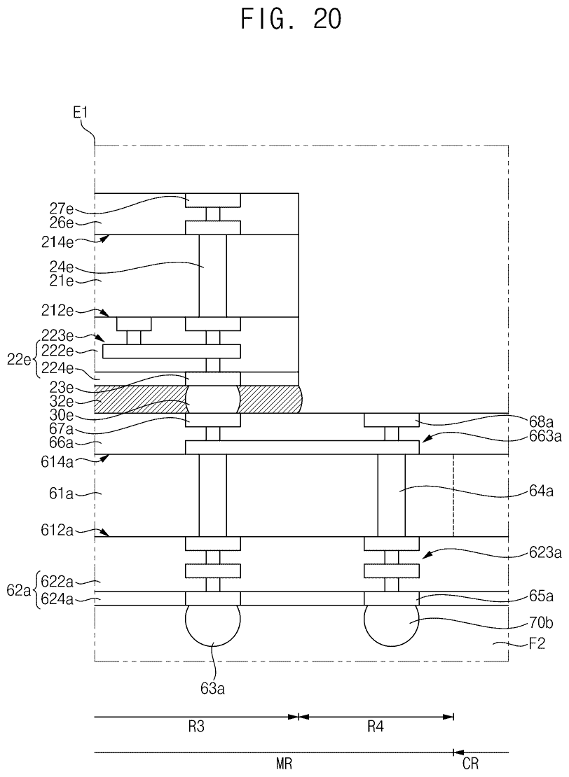

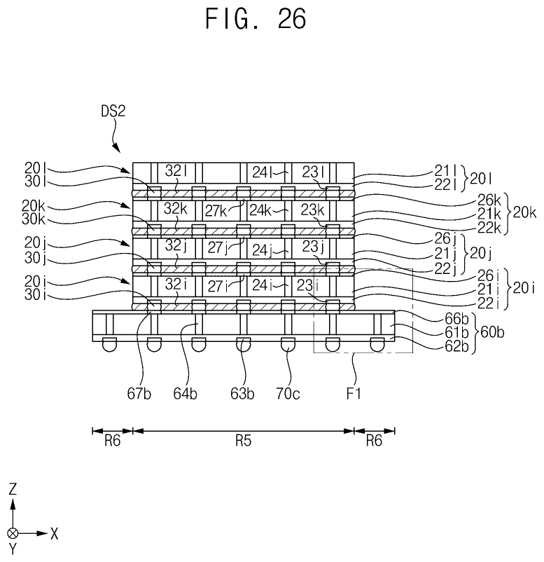

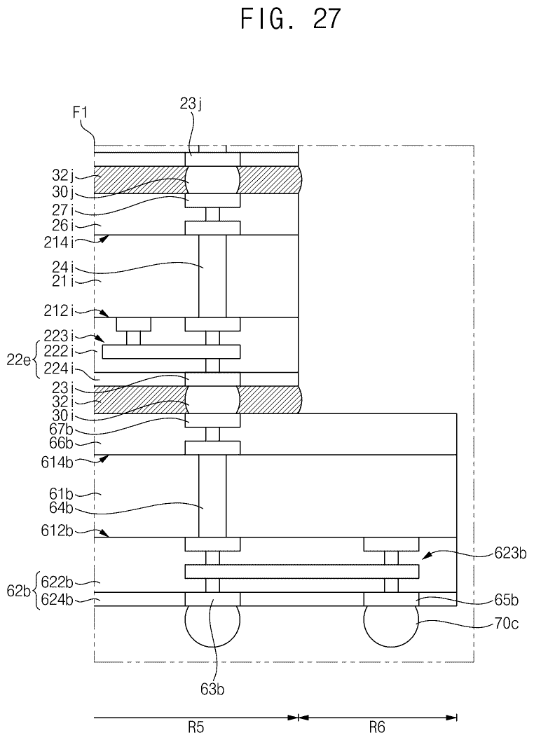

FIGS. 8 to 30 are views illustrating a method of manufacturing a semiconductor package in accordance with example embodiments. FIG. 8 is a plan view illustrating a first wafer including buffer dies. FIGS. 9, 11, 13, 16, 17, 18, 19, 21, 22, 23, 24, 25, 26, 28, 29, and 30 are cross-sectional views illustrating a method of manufacturing a semiconductor package in accordance with example embodiments. FIGS. 9, 11, 13, 16, 17, and 19 are cross-sectional views including a cross-sectional portion taken along the line C1-C1′ in FIG. 8. FIG. 10 is an enlarged cross-sectional view illustrating a portion C2 in FIG. 9. FIG. 12 is an enlarged cross-sectional view illustrating a portion C3 in FIG. 11. FIG. 14 is a plan view of FIG. 13. FIG. 13 is a cross-sectional view taken along the line D1-D1′ in FIG. 14. FIG. 15 is a side view illustrating a process of forming vertical wires on the first wafer in FIG. 14. FIG. 20 is an enlarged cross-sectional view illustrating a portion E1 in FIG. 19. FIG. 27 is an enlarged cross-sectional view illustrating a portion F1 in FIG. 26.

Referring to FIGS. 8 to 18, first, a base stack structure may be formed on a first carrier substrate C1.

As illustrated in FIGS. 8 to 11, a first group of core dies (e.g., the first core die 20a, the second core die 20b, the third core die 20c, and the fourth core die 20d) may be sequentially stacked on a first wafer W1 including buffer dies (die to wafer bonding process).

In example embodiments, first, conductive bumps 70a as external connection members may be formed on a front surface of the first wafer W1, and an adhesive film F1 may be formed on the front surface of the first wafer W1 to cover the conductive bumps 70. Then, the first wafer W1 may be attached to the first carrier substrate C1 using the adhesive film F1.

As illustrated in FIG. 8, the first wafer W1 may include a mounting region MR on which the buffer die is placed and a cutting region SR surrounding the mounting region MR. As described below, after forming a plurality of the base stack structures on the first carrier substrate C1, the first wafer W1 may be cut along the cutting region SR to form individualized base stack structures.

In addition, the mounting region MR may include a first region R1 and a second region R2 at a side of the first region R1. The first group of core dies (e.g., the first core die 20a, the second core die 20b, the third core die 20c, and the fourth core die 20d) may be stacked on the first region R1. The second region R2 may be provided to surround the first region R1.

As illustrated in FIGS. 9 and 10, first core dies 20a may be placed on the first wafer W1 to correspond to the first regions R1 respectively. A first surface 212a of a substrate 21a of the first core die 20a may be stacked to face the first wafer W1.

In example embodiments, the first core die 20a may be mounted on the buffer die via first conductive bumps 30a. The first conductive bumps 30a may be formed as conductive connecting members on first bonding pads 23a of the first core die 20a, and a first adhesive layer 32a may be formed on a front surface of the first core die 20a to cover the first conductive bumps 30a. For example, the first adhesive layer 32a may include a thermosetting resin. The first adhesive layer 32a may include a non-conductive film NCF.

Then, a thermal compression process may be performed at a predetermined temperature (e.g., about 400° C. or less) to attach the first core die 20a onto the first wafer W1. In the thermal compression process, the non-conductive film may be liquefied to have fluidity and may flow between the first core die 20a and the first wafer W1. The non-conductive film having fluidity may flow between the first conductive bumps 30a and then be cured to fill a space between the first conductive bumps 30a. A portion of the first adhesive layer 32a, that is cured, may protrude from a side of the first core die 20a.

By the thermal compression process, the first conductive bump 30a on the first core die 20a may be bonded to a second bonding pad 17 of the buffer die. The first bonding pad 23a of the first core die 20a may be electrically connected to the second bonding pad 17 of the buffer die by the first conductive bump 30a.

The buffer die of the first wafer W1 may include a plurality of first wire bonding pads 18 in the second region R2. The plurality of first wire bonding pads 18 may be arranged within the second region R2 to be spaced apart along one side of the mounting region MR. The second bonding pads 17 and the first wire bonding pads 18 of the buffer die may be provided in a backside insulating layer 16 on a second surface 114 of the substrate 11. The second bonding pads 17 and the first wire bonding pads 18 of the buffer die may be electrically connected to the first bonding pads 13 by through electrodes 14 formed in the substrate 11. The second bonding pads 17 and the first wire bonding pads 18 of the buffer die may be electrically connected to each other by wiring 123 in the front insulating layer 12 on the first surface 112 of the substrate 11. In addition, the second bonding pads 17 and the first wire bonding pads 18 of the buffer die may be electrically connected to each other by wirings in the backside insulating layer 16 on the second surface 114 of the substrate 11.

The first core die 20a may be mounted on the buffer die via the first conductive bumps 30a, but it may not be limited thereto, and the first core die 20a may be bonded by die-to-wafer hybrid bonding. When the first wafer W1 and the first core die 20a are bonded to each other by die-to-wafer hybrid bonding, the second bonding pad 17 of the first wafer W1 and the first bonding pad 23a of the first core die 20a may be bonded to each other by copper-copper hybrid bonding (Cu—Cu Hybrid Bonding).

As illustrated in FIG. 11 and FIG. 12, processes the same as or similar to the processed described with reference to FIGS. 9 and 10 may be performed to the second core die 20b, the third core die 20c, and the fourth core die 20d that are sequentially stacked on the first core die 20a.

The second core die 20b may be stacked on the first core die 20a via first conductive bumps 30b. The second core die 20b may be attached on the first core die 20a by a first adhesive layer 32b. A first bonding pad 23b of the second core die 20b may be electrically connected to a second bonding pad 27a of the first core die 20a by the first conductive bump 30b.

The third core die 20c may be stacked on the second core die 20b via first conductive bumps 30c. The third core die 20c may be attached on the second core die 20b via a first adhesive layer 32c. A first bonding pad 23c of the third core die 20c may be electrically connected to a second bonding pad 27b of the second core die 20b by the first conductive bump 30c.

The fourth core die 20d may be stacked on the third core die 20c via first conductive bumps 30d. The fourth core die 20d may be attached on the third core die 20c via a first adhesive layer 32d. A first bonding pad 23d of the fourth core die 20d may be electrically connected to a second bonding pad 27c of the third core die 20c by the first conductive bump 30d.

Here, the fourth core die 20d may include a substrate 21d, a front insulating layer 22d provided on a first surface of the substrate 21a and having the first bonding pads 23d, and through electrodes 24d extending from the first surface of the substrate 21d to a predetermined depth. A second surface opposite to the first surface of the substrate 21a may be exposed to the outside.

In this embodiment, the first group of core dies stacked on the buffer die is illustrated as including four stacked core dies (e.g., the first core die 20a, the second core die 20b, the third core die 20c, and the fourth core die 20d), however, it may not be limited thereto, and for example, the first group of core dies may include 8 or 12 stacked core dies on the buffer die.

As illustrated in FIGS. 13 to 15, a plurality of first conductive wires 40a as vertical conductive structures may be formed on the plurality of first wire bonding pads 18 of the buffer die. The first conductive wires 40a may extend in a vertical direction (Z direction) from the first wire bonding pads 18, respectively.

For example, the first conductive wires 40a may be formed by a bonding wire process. The first conductive wires 40a may be bonding wires formed by a bonding wire process.

As illustrated in FIG. 15, one end portion of a wire CW drawn out from a capillary CP of a wire bonding apparatus may be bonded to the first wire bonding pad 18, and then the capillary CP may draw out the wire while moving in the vertical direction (Z direction). The, when the wire is extended to a predetermined length, a portion of the wire may be cut to form the first conductive wire 40a. A height of the first conductive wire 40a from the buffer die may be the same as or similar to a height of the fourth core die 20d from the buffer die.

Accordingly, the first conductive wire 40a may include a wire body extending in the vertical direction, a first bonding end portion provided at a first end portion of the wire body and bonded to the first wire bonding pad 18, and a second bonding end portion provided at a second end portion of the wire body. A diameter of the wire body may be within a range of 10μm to 40μm.

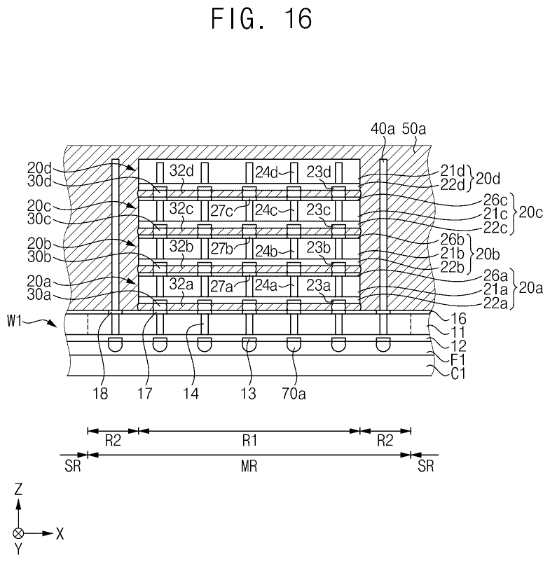

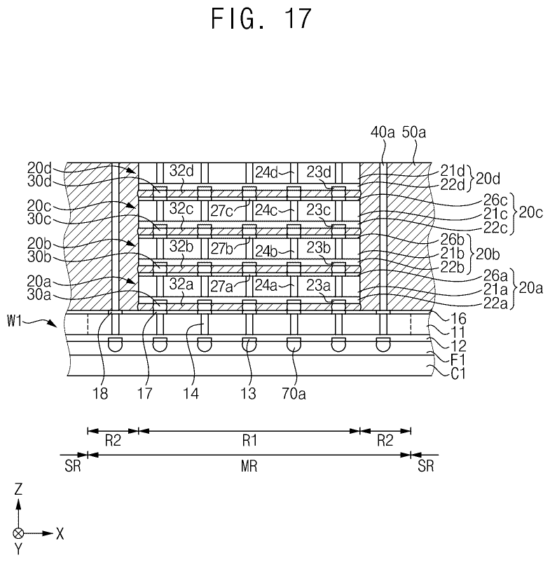

As illustrated in FIGS. 16 and 17, a first sealing member 50a may be formed on the first wafer W1 to cover the first core die 20a, the second core die 20b, the third core die 20c, and the fourth core die 20d and the plurality of first conductive wires 40a, and an upper portion of the first sealing member 50a and the second surface of the substrate 21d of the fourth core die 20d may be partially removed to expose one end portions of the through electrodes 24d and one end portions of the first conductive wires 40a. The first sealing member 50a may cover outer side surfaces of the first core die 20a, the second core die 20b, the third core die 20c, and the fourth core die 20d. The first sealing member 50a may cover the outer side surfaces of the first conductive wires 40a.

The first sealing member may include a thermosetting resin such as, for example, an epoxy mold compound EMC. The first sealing member may include fillers and an epoxy resin that acts as a binder for the fillers.

Then, a grinding process such as a back lap process may be performed to partially remove the upper portion of the first sealing member 50a and the second surface of the substrate 21d of the fourth core die 20d, and then an etching process such as a silicon recess process may be performed to expose the one end portions of the through electrodes 24d. Accordingly, a thickness of the substrate 21d may be reduced to a desired thickness. For example, the substrate 21d may have a thickness in a range of about 20μm to 50μm.

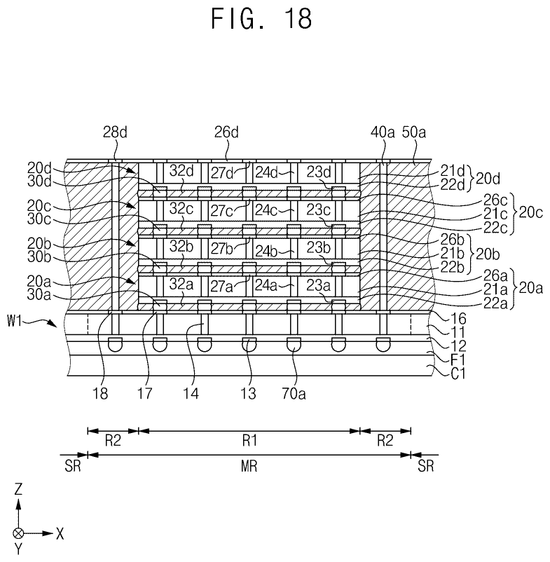

As illustrated in FIG. 18, a backside insulating layer 26d may be formed on the second surface of the substrate 21d of the fourth core die 20d and the upper surface of the first sealing member 50a.

In particular, the backside insulating layer 26d as a passivation layer having second bonding pads 27d and second wire bonding pads 28d may be formed on the second surface of the substrate 21d of the fourth core die 20d and the upper surface of the first sealing member 50a.

For example, after forming the backside insulating layer 26d on the second surface of the substrate 21d of the fourth core die 20d and the upper surface of the first sealing member 50a, a first opening that exposes one end portion of the through electrode 24d and a second opening that exposes one end portion of the first conductive wire 40a may be formed in the backside insulating layer 26d, and a plating process may be performed to form the second bonding pad 27d in the first opening and the second wire bonding pad 28d in the second opening. The second bonding pad 27d may be disposed on the exposed surface of the through electrode 24d. The second wire bonding pad 28d may be disposed on the exposed surface of the first conductive wire 40a. The backside insulating layer 26d may include silicon oxide, carbon-doped silicon oxide, silicon carbonitride, or the like. Accordingly, the first bonding pads 23d and the second bonding pads 27d may be electrically connected to each other by the through electrode 24d. The first wire bonding pads 18 and the second wire bonding pads 28d may be electrically connected to each other by the first conductive wire 40a.

Thus, the base stack structure including the buffer die, the first group of core dies (e.g., the first core die 20a, the second core die 20b, the third core die 20c, and the fourth core die 20d) sequentially stacked on the buffer die, the plurality of first conductive wires 40a extending in the vertical direction from the plurality of first wire bonding pads 18 on the second region R2 of the buffer die, and the first sealing member 50a on the buffer die covering the first group of core dies (e.g., the first core die 20a, the second core die 20b, the third core die 20c, and the fourth core die 20d) and the plurality of first conductive wires 40a and exposing one end portions of the first conductive wires 40a, may be formed on the first carrier substrate C1. Each of the first group of core dies (e.g., the first core die 20a, the second core die 20b, the third core die 20c, and the fourth core die 20d) may include the substrate 21a, 21b, 21c, 21d, the front insulating layer 22a, 22b, 22c, 22d, and the backside insulating layer 26a, 26b, 26c, 26d. The backside insulating layer 26d of the fourth core die 20d, which may be an uppermost core die, may extend laterally from the second surface of the substrate 21d to cover an upper surface of the first sealing member 50a.

Referring to FIGS. 19 to 25, processes the same as or similar to the processes described with reference to FIGS. 8 to 18 may be performed to form a first die stack structure DS1 on a second carrier substrate C2.

As illustrated in FIGS. 19 to 21, a second group of core dies (e.g., the fifth core die 20e, the sixth core die 20f, the seventh core die 20g, and the eighth core die 20h) may be sequentially stacked on the second wafer W2 including first interposers (die-to-wafer bonding process).

In example embodiments, third conductive bumps 70b as external connection members may be formed on a front surface of the second wafer W2, and an adhesive film F2 may be formed on the front surface of the second wafer W2 to cover the third conductive bumps 70b. Then, the second wafer W2 may be attached onto the second carrier substrate C2 using the adhesive film F2.

The second wafer W2 may include a mounting region MR, on which the core die is placed, and a cutting region SR surrounding the mounting region MR. As described below, after forming a plurality of the first die stack structures on the second carrier substrate C2, the second wafer W2 may be cut along the cutting region SR to form individualized first die stack structures.

In addition, the mounting region MR may include a third region R3 and a fourth region R4 at a side of the third region R3. The second group of core dies (e.g., the fifth core die 20e, the sixth core die 20f, the seventh core die 20g, and the eighth core die 20h) may be stacked on the third region R3. The fourth region R4 may be provided to surround the third region R3.

As illustrated in FIGS. 19 and 20, fifth core dies 20e may be placed on the second wafer W2 to correspond to the third regions R3 respectively. A first surface 212e of a substrate 21e of the fifth core die 20e may be stacked to face the second wafer W2.

In example embodiments, the fifth core die 20e may be mounted on the first interposer via second conductive bumps 30e. The second conductive bumps 30e may be formed as conductive connecting members on first bonding pads 23e of the fifth core die 20e, and a second adhesive layer 32e may be formed on a front surface of the fifth core die 20e to cover the second conductive bumps 30e. For example, the second adhesive layer 32e may include a thermosetting resin. The second adhesive layer 32e may include a non-conductive film NCF.

The second conductive bump 30e on the fifth core die 20e may be bonded to a second bonding pad 67a of the first interposer by a thermal compression process. The first bonding pad 23e of the fifth core die 20e may be electrically connected to the second bonding pad 67a of the first interposer by the second conductive bump 30e.

The first interposer of the second wafer W2 may include a plurality of third wire bonding pads 68a at (e.g., in or on) an upper surface of the fourth region R4. Each of the first interposers of the second wafer W may include first bonding pads 63a at (e.g., in or on) a lower surface of the third region R3 and first lower connection pads 65a at (e.g., in or on) a lower surface of the fourth region R4. The plurality of third wire bonding pads 68a may be arranged within the fourth region R4 to be spaced apart along one side of the mounting region MR. The second bonding pads 67a and the third wire bonding pads 68a of the first interposer may be provided in a backside insulating layer 66a on a second surface 614a of the interposer substrate 61a. The second bonding pads 67a of the first interposer may be electrically connected to the first bonding pads 63a by through electrodes 64a. The third wire bonding pads 68a of the first interposer may be electrically connected to the first lower connection pads 65a by the through electrodes 64a. The second bonding pads 67a and the third wire bonding pads 68a of the first interposer may be electrically connected to each other by wirings 663a in the backside insulating layer 66a on the second surface 614a of the interposer substrate 61a. In addition, the second bonding pads 67a and the third wire bonding pads 68a of the first interposer may be electrically connected to each other by wirings in a front insulating layer 62a on the first surface 612a of the interposer substrate 61a.

The fifth core die 20e may be mounted on the first interposer via the second conductive bumps 30e, but it may not be limited thereto, and the fifth core die 20e may be bonded by die-to-wafer hybrid bonding. When the second wafer W2 and the fifth core die 20e are bonded to each other by die-to-hybrid bonding, the second bonding pad 67a of the second wafer W2 and the first bonding pad 23e of the fifth core die 20e may be bonded to each other by copper-copper hybrid bonding (Cu—Cu Hybrid Bonding).

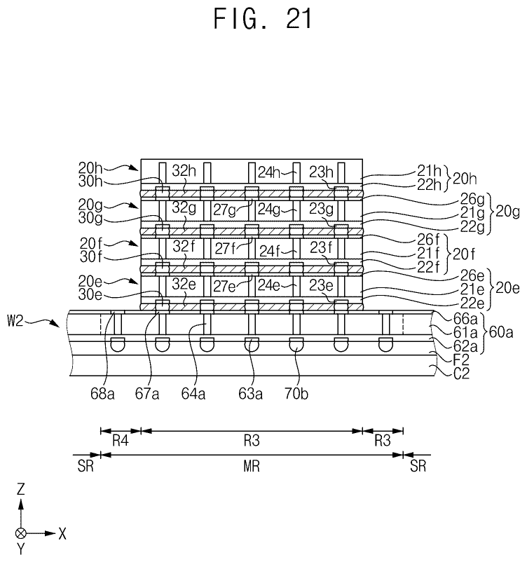

As illustrated in FIG. 21, processes the same as or similar to the processed described with reference to FIGS. 19 and 20 may be performed to sequentially stack the sixth core die 20f, the seventh core die 20g, and the eighth core die 20h on the fifth core die 20e.

The sixth core die 20f may be stacked on the fifth core die 20e via second conductive bumps 30f. The sixth core die 20f may be attached to the fifth core die 20e by a second adhesive layer 32f. A first bonding pad 23f of the sixth core die 20f may be electrically connected to a second bonding pad 27e of the fifth core die 20e by the second conductive bump 30f.

The seventh core die 20g may be stacked on the sixth core die 20f via second conductive bumps 30g. The seventh core die 20g may be attached on the sixth core die 20f by a second adhesive layer 32g. A first bonding pad 23g of the seventh core die 20g may be electrically connected to a second bonding pad 27f of the sixth core die 20f by the second conductive bump 30g.

The eighth core die 20h may be stacked on the seventh core die 20g via second conductive bumps 30h. The eighth core die 20h may be attached on the seventh core die 20g by a second adhesive layer 32h. A first bonding pad 23h of the eighth core die 20h may be electrically connected to a second bonding pad 27g of the seventh core die 20g by the second conductive bump 30h.

Here, the eighth core die 20h may include a substrate 21h, a front insulating layer 22h provided on a first surface of the substrate 21h and having the first bonding pads 23h, and through electrodes 24h extending from the first surface of the substrate 21h to a predetermined depth. A second surface of the substrate 21h opposite to the first surface of the substrate 21h may be exposed to the outside.

In this embodiment, the second group of core dies stacked on the first interposer is illustrated as including four stacked core dies (e.g., the fifth core die 20e, the sixth core die 20f, the seventh core die 20g, and the eighth core die 20h). However, embodiments of the present disclosure are not limited thereto, and for example, the second group of core dies may include 8 or 12 stacked core dies on the first interposer.

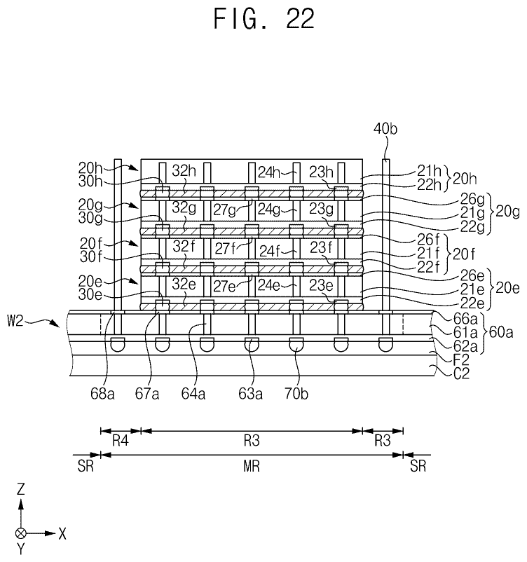

As illustrated in FIG. 22, a plurality of second conductive wires 40b as vertical conductive structures may be formed on the plurality of third wire bonding pads 68a of the first interposer. The second conductive wires 40b may extend vertically from the third wire bonding pads 68a, respectively.

For example, the second conductive wires 40b may be formed by a bonding wire process. The second conductive wires 40b may be bonding wires formed by a bonding wire process.

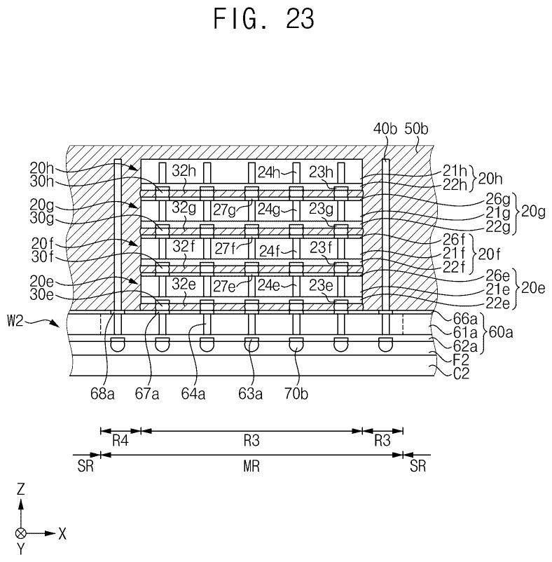

As illustrated in FIG. 23, a second sealing member 50b may be formed on the second wafer W2 to cover the fifth core die 20e, the sixth core die 20f, the seventh core die 20g, the eighth core die, 20h and the plurality of second conductive wires 40b. The second sealing member 50b may cover outer surfaces of the fifth core die 20e, the sixth core die 20f, the seventh core die 20g, and the eighth core die 20h. The second sealing member 50b may cover outer surfaces of the second conductive wires 40b. The second sealing member may include a thermosetting resin such as, for example, an epoxy mold compound EMC. The second sealing member may include fillers and an epoxy resin that acts as a binder for the fillers.

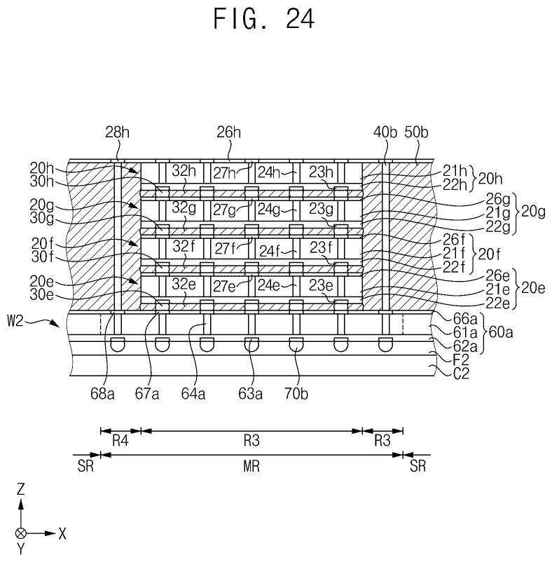

As illustrated in FIG. 24, an upper portion of the second sealing member 50b and the second surface of the substrate 21h of the eighth core die 20h may be partially removed to expose end portions of the through electrodes 24h and end portions of the second conductive wires 40b, and a backside insulating layer 26h may be formed on the second surface of the substrate 21h of the eighth core die 20h and the upper surface of the second sealing member 50b.

The backside insulating layer 26h may be provided with a second bonding pad 27h and a fourth wire bonding pad 28h. The second bonding pad 27h may be disposed on the exposed surface of the through electrode 24h. The fourth wire bonding pad 28h may be disposed on the exposed surface of the second conductive wire 40b. Accordingly, the first bonding pad 23h and the second bonding pad 27h may be electrically connected to each other by the through electrode 24h. The third wire bonding pad 68a and the fourth wire bonding pad 28h may be electrically connected to each other by the second conductive wire 40b.

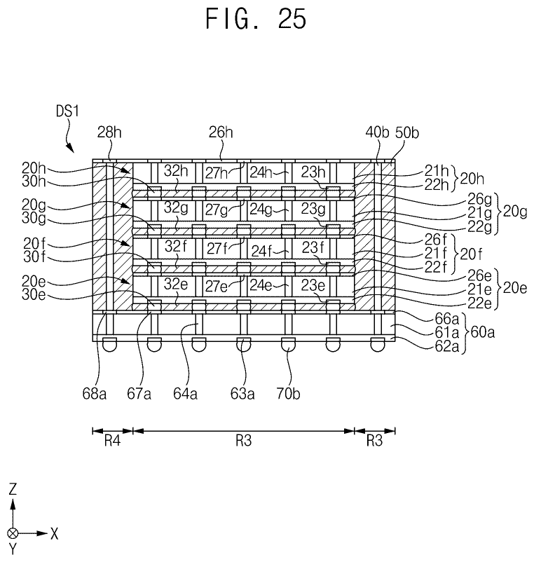

As illustrated in FIG. 25, the second wafer W2 and the second sealing member 50b may be cut along the cutting region SR to form individualized first die stack structures DS1. The first die stack structure DS1 may include a first interposer 60a, the second group of core dies (e.g., the fifth core die 20e, the sixth core die 20f, the seventh core die 20g, and the eighth core die 20h) sequentially stacked on the first interposer 60a, the plurality of second conductive wires 40b extending in a vertical direction from the plurality of third wire bonding pads 68a on a fourth region R4 of the first interposer 60a, and the second sealing member 50b on the first interposer 60a covering the second group of core dies (e.g., the fifth core die 20e, the sixth core die 20f, the seventh core die 20g, and the eighth core die 20h) and the plurality of second conductive wires 40b and exposing end portions of the second conductive wires 40b. Each of the second group of core dies (e.g., the fifth core die 20e, the sixth core die 20f, the seventh core die 20g, and the eighth core die 20h) may include the substrate 21e, 21f, 21g, 21h, the front insulating layer 22e, 22f, 22g, 22h, and the backside insulating layer 26e, 26f, 26g, 26h. The backside insulating layer 26h of the eighth core die 20h, which may be an uppermost core die, may extend laterally from the second surface of the substrate 21g to cover an upper surface of the second sealing member 50b.

Referring to FIGS. 26 and 27, processes the same as or similar to the processes described with reference to FIGS. 19 to 25 may be performed to form a second die stack structure DS2 on a third carrier substrate.

In example embodiments, a third group of core dies (e.g., the ninth core die 20i, the tenth core die 20j, the eleventh core die 20k, and the twelfth core die 20l) may be sequentially stacked on the third wafer including second interposers (die-to-wafer bonding process).

First, fourth conductive bumps 70c as external connection members may be formed on a front surface of the third wafer, and an adhesive film may be formed on the front surface of the third wafer to cover the fourth conductive bumps 70c. Then, the third wafer may be attached to the third carrier substrate using the adhesive film.

The third wafer may include a mounting region on which the core die is placed and a cutting region surrounding the mounting region. As described below, after forming a plurality of the second die stack structures on the third carrier substrate, the third wafer may be cut along the cutting region to form individualized second die stack structures.

In addition, the mounting region may include a fifth region R5 and a sixth region R6 at a side of the fifth region R5. The third group of core dies (e.g., the ninth core die 20i, the tenth core die 20j, the eleventh core die 20k, and the twelfth core die 20l) may be stacked on the fifth region R5. The sixth region R6 may be provided to surround the fifth area R5.

As illustrated in FIGS. 26 and 27, ninth core dies 20i may be placed on the third wafer so as to correspond to the fifth regions R5 respectively. A first surface 212i of a substrate 21i of the ninth core die 20i may be stacked to face the third wafer.

In example embodiments, the ninth core die 20i may be mounted on the second interposer via second conductive bumps 30i. The second conductive bumps 30i may be formed as conductive connecting members on first bonding pads 23i of the ninth core die 20i, and a second adhesive layer 32i may be formed on a front surface of the ninth core die 20i to cover the second conductive bumps 30i. For example, the second adhesive layer 32i may include a thermosetting resin. The second adhesive layer 32i may include a non-conductive film NCF.

Each of the second interposers of the third wafer may include first bonding pads 63b at (e.g., in or on) a lower surface of the fifth region R5 and second lower connection pads 65b at (e.g., in or on) a lower surface of the sixth region R6. The first bonding pads 63b and the second lower connection pads 68b of the second interposer may be provided in a front insulating layer 62b on a first surface 612b of the interposer substrate 61b. The second bonding pads 67b of the second interposer may be electrically connected to the first bonding pads 63b by through electrodes 64b. The second lower connection pads 65b of the second interposer may be electrically connected to the second bonding pads 67b by wiring 623b and the through electrodes 64b in a front insulating layer 62b.

The ninth core die 20i may be mounted on the second interposer via the second conductive bumps 30i, but it may not be limited thereto, and the ninth core die 20i may be bonded by die-to-wafer hybrid bonding. When the third wafer and the ninth core die 20i are bonded to each other via die-to-hybrid bonding, the second bonding pad 67b of the third wafer and the first bonding pad 23i of the ninth core die 20i may be bonded to each other by copper-copper hybrid bonding (Cu—Cu Hybrid Bonding).

Similarly, the tenth core die 20j, the eleventh core die 20k, and the twelfth core die 20l may be sequentially stacked on the ninth core die 20i via second conductive bumps 30j, 30k, 30l. The tenth core die 20j, the eleventh core die 20k, and the twelfth core die 20l l may be sequentially attached onto the ninth core die 20i by adhesive layers 32j, 32k, 32l.

In this embodiment, the third group of core dies stacked on the second interposer is illustrated as including four stacked core dies (e.g., the ninth core die 20i, the tenth core die 20j, the eleventh core die 20k, and the twelfth core die 20l). However, embodiments of the present disclosure are not limited thereto, and for example, the third group of core dies may include 8 or 12 stacked core dies on the second interposer.

Then, the third wafer may be cut along the cutting region to form individualized second die stack structures DS2.

The second die stack structure DS2 may include a second interposer 60b and the third group of core dies (e.g., the ninth core die 20i, the tenth core die 20j, the eleventh core die 20k, and the twelfth core die 20l) sequentially stacked on the second interposer 60b. Additionally, the second die stack structure DS2 may further include a sealing member covering the third group of core dies (e.g., the ninth core die 20i, the tenth core die 20j, the eleventh core die 20k, and the twelfth core die 20l) on the second interposer 60b.

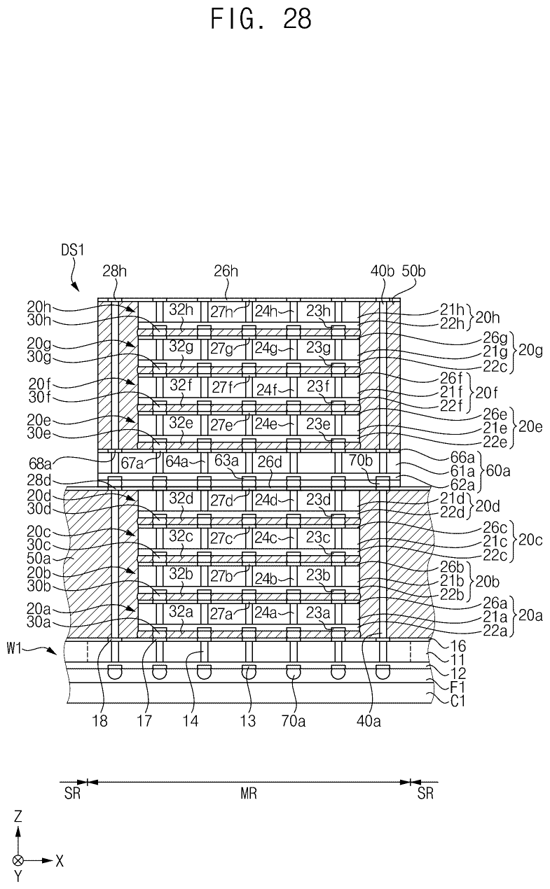

Referring to FIG. 28, the first die stack structure DS1 of FIG. 25 may be stacked on the base stack structure of FIG. 18. The first die stack structure DS1 may be arranged on the base stack structure such that the third region R3 of the first interposer 60a overlaps the first region R1 of the buffer die and the fourth region R4 of the first interposer 60a overlaps the second region R2 of the buffer die.

In example embodiments, the first interposer 60a of the first die stack structure DS1 may be mounted on the base stack structure via the third conductive bumps 70b. The third conductive bumps 70b on the first interposer 60a may be bonded to the second bonding pad 27d and the second wire bonding pad 28d of the fourth core die 20d of the base stack structure, respectively, by a thermal compression process. Accordingly, the through electrode 24d of the fourth core die 20d may be electrically connected to the second bonding pad 67a of the first interposer 60a by the third conductive bump 70b. The plurality of first conductive wires 40a of the base stack structure may be electrically connected to the plurality of first lower connection pads 65a of the first interposer 60a by the third conductive bumps 70b, respectively.

Since the first lower connection pad 65a is electrically connected to the third wire bonding pad 68a by the through electrode 64a, the first conductive wire 40a may be electrically connected to the second conductive wire 40b of the first die stack structure DS1. Since the third wire bonding pad 68a is electrically connected to the second bonding pad 67a of the first interposer 60a by the wiring 663a in the backside insulating layer 66a or the wiring in the front insulating layer 62a, the first conductive wire 40a may be electrically connected to the through electrode 24e of the fifth core die 20e of the first die stack structure DS1.

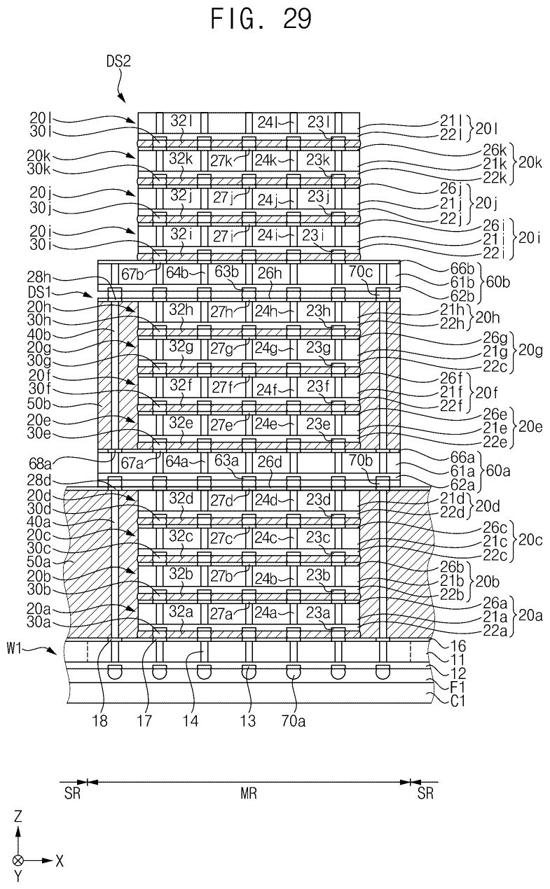

Referring to FIG. 29, the second die stack structure DS2 of FIG. 26 may be stacked on the first die stack structure D1 of FIG. 28. The second die stack structure DS2 may be arranged on the first die stack structure DS1 such that the fifth region R5 of the second interposer 60b overlaps the third region R3 of the first interposer 60a and the sixth region R6 of the second interposer 60b overlaps the fourth region R4 of the first interposer 60a.

In example embodiments, the second interposer 60b of the second die stack structure DS2 may be mounted on the first die stack structure DS1 via the fourth conductive bumps 70c. The fourth conductive bumps 70c on the second interposer 60b may be bonded to the second bonding pad 27h and the fourth wire bonding pad 28h of the eighth core die 20h of the first die stack structure, respectively, by a thermal compression process. Accordingly, the through electrode 24h of the eighth core die 20h may be electrically connected to the second bonding pad 67b of the second interposer 60b by the fourth conductive bump 70c. The plurality of second conductive wires 40b of the first die stack structure DS1 may be electrically connected to the plurality of second lower connection pads 65b of the second interposer 60b by the fourth conductive bumps 70c, respectively.

Since the second lower connection pad 65b is electrically connected to the second bonding pad 67b by the wiring 623b and the through electrode 64b in the front insulating layer 62b, the second conductive wire 40b may be electrically connected to the through electrode 24i of the ninth core die 20i of the second die stack structure DS2.

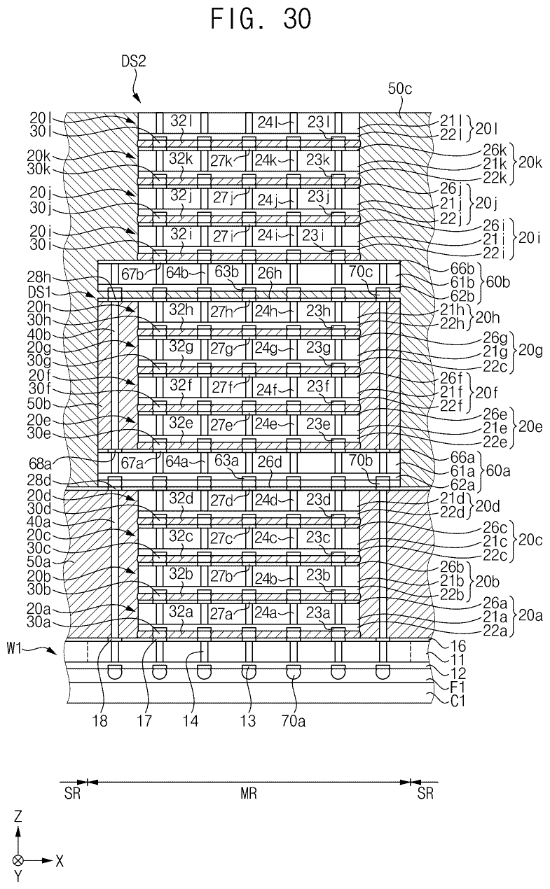

Referring to FIG. 30, a third sealing member 50c may be formed to cover the first die stack structure DS1 and the second die stack structure DS2 sequentially stacked on the base stack structure.

For example, a third sealing member 50c as a gap filling portion may be formed on the base stack structure to fill between the first die stack structure DS1 and the second die stack structure DS2. The third sealing member 50c may expose an upper surface of the twelfth core die 20l, which may be an uppermost die of the second die stack structure DS2. The third sealing member 50c may be in direct contact with outer side surfaces of the first die stack structure DS1 and the second die stack structure DS2.

For example, the third sealing member may include a thermosetting resin. The third sealing member may include an epoxy mold compound EMC. The third sealing member may include UV resin, polyurethane resin, silicone resin, silica filler, etc.

Then, portions of the first wafer W1 and the third sealing member 50c may be cut along the cutting region SR (e.g., a scribe lane region) to form the semiconductor package 100 of FIG. 1.

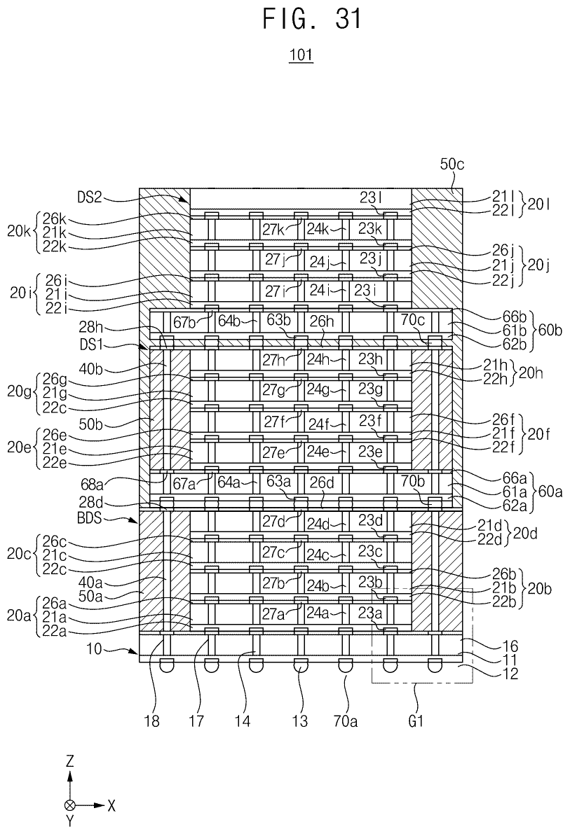

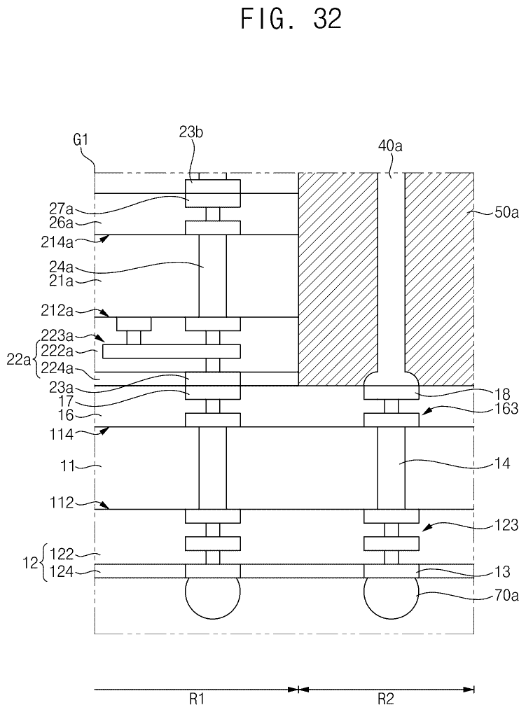

FIG. 31 is a cross-sectional view illustrating a semiconductor package in accordance with example embodiments. FIG. 32 is an enlarged cross-sectional view illustrating a portion G1 in FIG. 31. The semiconductor package is substantially the same as or similar to the semiconductor package described with reference to FIGS. 1 to 7 except for a base stack structure and a mounting method of core dies in a die stack structure. Thus, same reference numerals will be used to refer to the same or like elements and any further repetitive explanation concerning the above elements may be omitted.

Referring to FIGS. 31 and 32, a semiconductor package 100 may include a base die stack structure BDS, at least one first die stack structure DS1 stacked on the base die stack structure BDS, and a second die stack structure DS2 stacked on the at least one first die stack structure DS1.

In example embodiments, the base die stack structure BDS may include a buffer die 10, a first group of core dies (e.g., a first core die 20a, a second core die 20b, a third core die 20c, and a fourth core die 20d) sequentially stacked on the buffer die 10, a plurality of first conductive wires 40a extending in a vertical direction from a plurality of first wire bonding pads 18 on a second region R2 of the buffer die 10, and a first sealing member 50a on the buffer die 10 covering the first group of core dies (e.g., the first core die 20a, the second core die 20b, the third core die 20c, and the fourth core die 20d) and the plurality of first conductive wires 40a and exposing end portions of the first conductive wires 40a.

The first group of core dies (e.g., the first core die 20a, the second core die 20b, the third core die 20c, and the fourth core die 20d) may be sequentially stacked on the buffer die 10 by a hybrid bonding method. For example, a first core die 20a may be bonded on the buffer die 10 of a first wafer by die-to-wafer hybrid bonding. Similarly, the second core die 20b, the third core die 20c, and the fourth core die 20d may be sequentially stacked on the buffer die 10 by die-to-wafer hybrid bonding.

As illustrated in FIG. 32, a first core die 20a and the buffer die 10 may be bonded to each other by hybrid bonding. A second bonding pad 17 of the buffer die 10 and a first bonding pad 23a of the first core die 20a may be bonded to each other by copper-copper hybrid bonding (Cu—Cu Hybrid Bonding). A front insulating layer 22a on a front surface of the first core die 20a (e.g., a first surface 212a of the substrate 21a) may be directly bonded to a backside insulating layer 16 of the substrate 11 of the buffer die 10.

In example embodiments, the first die stack structure DS1 may be stacked on the base die stack structure BDS. The first die stack structure DS1 may include a first interposer 60a, a second group of core dies (e.g., a fifth core die 20e, a sixth core die 20f, a seventh core die 20g, and an eighth core die 20h) sequentially stacked on the first interposer 60a, a plurality of second conductive wires 40b extending in the vertical direction from a plurality of third wire bonding pads 68a on a fourth region R4 of the first interposer 60a, and a second sealing member 50b on the first interposer 60a covering the second group of core dies (e.g., the fifth core die 20e, the sixth core die 20f, the seventh core die 20g, and the eighth core die 20h) and the plurality of second conductive wires 40b and exposing end portions of the second conductive wires 40b.

The second group of core dies (e.g., the fifth core die 20e, the sixth core die 20f, the seventh core die 20g, and the eighth core die 20h) may be sequentially stacked on the first interposer 60a by a hybrid bonding method. For example, a fifth core die 20e may be bonded on the first interposer of a second wafer by die-to-wafer hybrid bonding. Similarly, a sixth core die 20f, a seventh core die 20g, and an eighth core die 20h may be sequentially stacked on the first interposer by die-to-wafer hybrid bonding.

In example embodiments, the second die stack structure DS2 may be stacked on the first die stack structure DS1. The second die stack structure DS2 may include a second interposer 60b and a third group of core dies (e.g., a ninth core die 20i, a tenth core die 20j, an eleventh core die 20k, and a twelfth core die 20l) sequentially stacked on the second interposer 60b.

The third group of core dies (e.g., the ninth core die 20i, the tenth core die 20j, the eleventh core die 20k, and the twelfth core die 20l) may be sequentially stacked on the second interposer 60b by a hybrid bonding method. For example, a ninth core die 20i may be bonded on the second interposer of a third wafer by die-to-wafer hybrid bonding. Similarly, a tenth core die 20j, an eleventh core die 20k, and a twelfth core die 20l may be sequentially stacked on the second interposer by die-to-wafer hybrid bonding.

The semiconductor package may include semiconductor devices such as logic devices or memory devices. The semiconductor package may include logic devices such as central processing units (CPUs), main processing units (MPUs), or application processors (Aps), or the like, and volatile memory devices such as dynamic random-access memory (DRAM) devices, HBM devices, or non-volatile memory devices such as flash memory devices, parameter random-access memory (PRAM) devices, magnetoresistive random-access memory (MRAM) devices, resistive random-access memory (ReRAM) devices, or the like.

Non-limiting example embodiments have been described above with reference to the accompanying drawings. Although a few example embodiments have been described, those skilled in the art will readily appreciate that many modifications are possible in example embodiments without materially departing from the spirit and scope of the present disclosure. Accordingly, all such modifications are intended to be included within the scope of the present disclosure.

What is claimed is:

1. A semiconductor package, comprising:
a buffer die comprising a first region and a second region at a side of the first region, wherein a plurality of first wire bonding pads are in an upper surface of the second region;
a first group of core dies sequentially stacked on the first region of the buffer die;
a first interposer on an uppermost core die among the first group of core dies, the first interposer comprising a third region overlapping the first region and a fourth region overlapping the second region, wherein a plurality of first lower connection pads are in a lower surface of the fourth region to face the plurality of first wire bonding pads, respectively;
a plurality of first conductive wires extending vertically from the plurality of first wire bonding pads between the second region of the buffer die and the fourth region of the first interposer, the plurality of first conductive wires connected to the plurality of first lower connection pads, respectively; and
a second group of core dies sequentially stacked on the first interposer.

2. The semiconductor package of claim 1, wherein the first group of core dies are connected to each other and the buffer die via first conductive bumps, and
wherein the second group of core dies are connected to each other and the first interposer via second conductive bumps.

3. The semiconductor package of claim 2, further comprising:
first adhesive layers between core dies of the first group of core dies and attaching the core dies of the first group of core dies to each other; and
second adhesive layers between core dies of the second group of core dies and attaching the core dies of the second group of core dies to each other.

4. The semiconductor package of claim 1, further comprising:
a first sealing member on the buffer die, the first group of core dies, and the plurality of first conductive wires.

5. The semiconductor package of claim 4, wherein a backside insulating layer of the uppermost core die, among the first group of core dies, is on an upper surface of the first sealing member.

6. The semiconductor package of claim 4, further comprising:
a plurality of second wire bonding pads respectively on end portions of the plurality of first conductive wires, the end portions exposed from an upper surface of the first sealing member; and
third conductive bumps between the plurality of second wire bonding pads and the plurality of first lower connection pads.

7. The semiconductor package of claim 1, wherein each of the first group of core dies and the second group of core dies comprises:
a substrate comprising a first surface and a second surface opposite to the first surface;
a front insulating layer on the first surface of the substrate and comprising first bonding pads;
a backside insulating layer on the second surface of the substrate and comprising second bonding pads; and
through electrodes penetrating the substrate and connected to the first bonding pads and the second bonding pads.

8. The semiconductor package of claim 7, wherein the plurality of first lower connection pads of the first interposer are connected to at least one from among the through electrodes of the second group of core dies.

9. The semiconductor package of claim 1, wherein the first interposer comprises a plurality of third wire bonding pads on an upper surface of the fourth region, and
wherein the semiconductor package further comprises:
a second interposer on an uppermost core die among the second group of core dies, the second interposer comprising a fifth region overlapping the third region and a sixth region overlapping the fourth region, wherein a plurality of second lower connection pads are in a lower surface of the sixth region to face the plurality of third wire bonding pads, respectively;
a plurality of second conductive wires extending in a vertical direction from the plurality of third wire bonding pads between the fourth region of the first interposer and the sixth region of the second interposer, the plurality of second conductive wires connected to the plurality of second lower connection pads, respectively; and
a third group of core dies sequentially stacked on the second interposer.

10. The semiconductor package of claim 9, wherein the plurality of second lower connection pads of the second interposer are connected to core dies, among the third group of core dies, on an upper surface of the second interposer.

11. A semiconductor package, comprising:
a base stack structure comprising:
a buffer die comprising a first region and a second region at a side of the first region;
a first group of core dies sequentially stacked on the first region of the buffer die;
a plurality of first conductive wires extending in a vertical direction from a plurality of first wire bonding pads on the second region of the buffer die; and
a first sealing member on the buffer die, the first group of core dies, and the plurality of first conductive wires, the first sealing member exposing end portions of the plurality of first conductive wires; and
a first die stack structure on the base stack structure, the first die stack structure comprising:
a first interposer comprising a third region overlapping the first region and a fourth region overlapping the second region; and
a second group of core dies sequentially stacked on the first interposer,
wherein the plurality of first conductive wires are connected to the second group of core dies by the first interposer.

12. The semiconductor package of claim 11, wherein the first group of core dies are connected to each other and the buffer die via first conductive bumps, and
wherein the second group of core dies are connected to each other and the first interposer via second conductive bumps.

13. The semiconductor package of claim 12, further comprising:
first adhesive layers between core dies among the first group of core dies and attaching the core dies among the first group of core dies to each other; and
second adhesive layers between core dies among the second group of core dies and attaching the core dies among the second group of core dies to each other.

14. The semiconductor package of claim 11, wherein the first interposer comprises a plurality of first lower connection pads in a lower surface of the fourth region to face the plurality of first wire bonding pads, respectively, and
wherein the plurality of first conductive wires are connected to the plurality of first lower connection pads, respectively.

15. The semiconductor package of claim 14, wherein the base stack structure further comprises a plurality of second wire bonding pads respectively on the end portions of the plurality of first conductive wires, the end portions exposed from an upper surface of the first sealing member, and
wherein the first interposer is connected to the base stack structure via third conductive bumps that are interposed between the plurality of second wire bonding pads and the plurality of first lower connection pads.

16. The semiconductor package of claim 15, wherein a backside insulating layer of an uppermost core die, among the first group of core dies, is on the upper surface of the first sealing member.

17. The semiconductor package of claim 14, wherein each of the first group of core dies and the second group of core dies comprises:
a substrate comprising a first surface and a second surface opposite to the first surface;
a front insulating layer on the first surface of the substrate and comprising first bonding pads;
a backside insulating layer on the second surface of the substrate and comprising second bonding pads; and
through electrodes penetrating the substrate and electrically connected to the first bonding pads and the second bonding pads, and
wherein the plurality of first lower connection pads of the first interposer are connected to at least one from among the through electrodes of the second group of core dies.

18. The semiconductor package of claim 11, further comprising:
a second die stack structure on the first die stack structure, the second die stack structure comprising:
a second interposer comprising a fifth region overlapping the third region and a sixth region overlapping the fourth region; and
a third group of core dies sequentially stacked on the second interposer, and
wherein the first interposer further comprises:
a plurality of second conductive wires extending vertically from a plurality of third wire bonding pads, the plurality of third wire bonding pads being at an upper surface of the fourth region; and
a second sealing member on the first interposer, the second group of core dies, and the plurality of second conductive wires and exposing end portions of the plurality of second conductive wires, and
wherein the plurality of second conductive wires are connected to the third group of core dies by the second interposer.

19. The semiconductor package of claim 18, wherein the second interposer comprises a plurality of second lower connection pads in a lower surface of the sixth region to face the plurality of third wire bonding pads respectively, and
wherein the plurality of second conductive wires are connected to the plurality of second lower connection pads, respectively.

20. A semiconductor package, comprising:
a buffer die comprising a first region and a second region at a side of the first region, wherein a plurality of first wire bonding pads are in the second region;
a plurality of core dies sequentially stacked on the first region of the buffer die;
an interposer between a pair of core dies from among the plurality of core dies, the interposer comprising a third region overlapping the first region and a fourth region overlapping the second region, wherein a plurality of lower connection pads are in the fourth region to face the plurality of first wire bonding pads, respectively;
a plurality of conductive wires extending vertically between the buffer die and the interposer from the plurality of first wire bonding pads, the plurality of conductive wires being connected to the plurality of lower connection pads, respectively;
a sealing member between the buffer die and the interposer, the sealing member being on the plurality of conductive wires and on at least two from among the plurality of core dies, and exposing end portions of the plurality of conductive wires;
a plurality of second wire bonding pads respectively on the end portions of the plurality of conductive wires, the end portions exposed from an upper surface of the sealing member; and
conductive bumps between the plurality of second wire bonding pads and the plurality of lower connection pads.
